(19) United States
(12) Patent Application Publication
(10) Pub. No.: US 2026/0032928 A1
(43) Pub. Date: Jan. 29, 2026

(54) SEMICONDUCTOR DEVICE AND METHOD FOR FABRICATING SAME

(71) Applicant: WUHAN XINXIN SEMICONDUCTOR MANUFACTURING CO., LTD., Wuhan (CN)

(72) Inventors: Hu YANG, Wuhan (CN); Sheng HU, Wuhan (CN); Yu ZHOU, Wuhan (CN)

(21) Appl. No.: 19/265,609

(22) Filed: Jul. 10, 2025

(30) Foreign Application Priority Data
Jul. 25, 2024 (CN) 202411011973.5

(51) Int. Cl. H01L 23/00; H01L 21/66; H01L 25/00; H01L 25/065; H01L 25/18; H10B 80/00

(52) U.S. Cl. CPC H01L 24/80; H01L 22/12; H01L 22/32; H01L 24/08; H01L 25/0657; H01L 25/18; H01L 25/50; H10B 80/00; H01L 2224/08145; H01L 2224/80006; H01L 2224/80895; H01L 2224/80896; H01L 2224/80908; H01L 2225/06541; H01L 2225/06582; H01L 2225/06596; H01L 2924/1431; H01L 2924/1434; H01L 2924/3511; H01L 2924/37001

(57) ABSTRACT

A semiconductor device and a method for fabricating the same are disclosed. The semiconductor device includes a first wafer structure and at least one die stack layer stacked on a second side of the first wafer structure. The die stack has first test pad and second test pad, which can be used to test and screen the die in the die stack and the die stack, contributing to increased yield of the semiconductor device. Additionally, metal pad may be formed on a first side of the first wafer structure before the die stack is stacked on the first wafer structure, avoiding warpage or other distortion possibly otherwise caused by high-temperature treatment if they are formed after the die stack is stacked. This facilitates stacking of more dies and/or wafers together. The semiconductor device is obtainable according to the method.

### CROSS-REFERENCE TO RELATED APPLICATION

This application claims the priority of Chinese patent application number 202411011973.5, filed on Jul. 25, 2024 and entitled “SEMICONDUCTOR DEVICE AND METHOD FOR FABRICATING SAME”, the entire contents of which are incorporated herein by reference.

### TECHNICAL FIELD

The present invention relates to the field of semiconductor technology and, in particular, to a semiconductor device and a method for fabricating the same.

### BACKGROUND

Conventionally, the integration of multiple elements of semiconductor devices can be achieved using methods such as wafer-to-wafer bonding (W2W) and chip-to-wafer bonding (C2W), enabling the integration of different types of dies, thereby realizing heterogeneous integration. This provides a variety of advantages, including high performance, a small size and low power consumption.

However, when using W2W technology to achieve a stack of multiple wafers, the warpage issue of the resulting wafer stack structure becomes more serious at high temperature as the number of stacked wafers increases. Possible consequences of such warpage include layer and/or film fracture and unsuccessful retention on semiconductor processing equipment. Further, the yield of a wafer stack structure tends to lower than the yield of each wafer therein, and the more the stacked wafers, the lower the yield of the wafer stack structure, further the yield of individual die stacks obtained by dicing the wafer stack structure also decreases as the number of stacked wafers increases. Consequently, the number of stacked dies and/or wafers in a semiconductor device obtained by a W2W, C2W or like technique is greatly limited.

### SUMMARY OF THE INVENTION

The present invention provides a method for fabricating a semiconductor device, which allows a large number of dies to be stacked in the semiconductor device while mitigating the problems of warpage and yield degradation. Also provided is a semiconductor device obtained according to the method.

In one aspect, the present invention provides a method for fabricating a semiconductor device, comprising:
forming a first wafer structure comprising at least one first wafer, and forming at least one metal pad on a first side of the first wafer structure;
forming a second wafer structure comprising at least two vertically stacked second wafers that have passed a first test, wherein dies in respective second wafers are vertically interconnected to form a plurality of die stacks;
performing a second test on the plurality of die stacks in the second wafer structure to screen for the die stacks that pass the second test, and dicing the second wafer structure to obtain the die stacks that have passed the second test; and
stacking at least one die stack layer that has passed the second test on a second side of the first wafer structure, wherein the second side is opposite to the first side, and wherein the die stack is vertically interconnected with the first wafer structure.

Optionally, the first wafer structure may consist of a single first wafer, wherein the first wafer comprises a first substrate, and at least one first interconnect structure and a dielectric layer that are formed on a first surface of the first substrate. Additionally, the first top metal layer may be formed on the first surface of the first substrate before the die stack is stacked on the second side of the first wafer structure, the first top metal layer is connected to the first interconnect structure by via extending through a dielectric layer between the first interconnect structure and the first top metal layer. The first top metal layer may contain the metal pad.

Optionally, after the metal pad is formed, the method may further comprise:
forming a protective layer that covers a side of the first wafer where the metal pad is formed, and bonding a first carrier substrate to the protective layer; and
thinning the first substrate at a second surface that is opposite to the first surface, and forming at least one through-silicon via (TSV), a rewiring layer and a first bond layer that are connected to the first interconnect structure, wherein the first bond layer is used to hybrid bond the die stack to the first wafer structure.

Optionally, after the at least one die stack layer is stacked on the second side of the first wafer structure, the method may further comprise:
forming a molded plastic layer over the second side, wherein the molded plastic layer covers the first wafer structure, the die stacks, and fills each gap between the die stacks;
removing the first carrier substrate to expose the protective layer; and
forming at least one opening that exposes the metal pad in the protective layer.

Optionally, the first wafer structure may consist of at least two first wafers, which are stacked together, wherein before or after the stacking is completed, a first top metal layer containing the metal pad is formed on a first side of one of the first wafers, at which the other first wafer is not stacked.

Optionally, the method may further comprise:
after the metal pad is formed, forming a protective layer that covers the first side of the first wafer where the metal pad is formed, and bonding a first carrier substrate to the protective layer; and
after stacking the at least two first wafers, forming a first bond layer at an end of a resulting stack that is away from the metal pad, wherein the first bond layer is used to hybrid bond the die stack to the first wafer structure.

Optionally, forming the second wafer structure may comprise:
obtaining at least two second wafers each comprising a second top metal layer, wherein the second top metal layer comprises at least one first test pad;
performing the first test on the at least two first wafers using the first test pad, so as to screen for the second wafer that passes the first test; and
forming the second wafer structure by selecting at least two second wafers that have passed the first test, wherein in the second wafer structure, adjacent second wafers are hybrid bonded to form the plurality of die stacks.

Optionally, the second wafer structure comprises a first end, wherein the first test pad located in the second wafer at the first end is located away from the other second wafer(s) in the second wafer structure, and wherein the second test is performed on the die stack from the first end.

Optionally, the second top metal layer in the second wafer at the first end may further comprise at least one second test pad that is connected to the first test pad, wherein performing the second test on the die stack in the second wafer structure comprises: exposing the second test pad located at the first end; and performing the second test using the second test pad.

Optionally, performing the second test on the die stack in the second wafer structure may comprise:
exposing the first test pad located at the first end;
forming a top cladding metal layer that is located external to the first test pad, wherein the top cladding metal layer is connected to the first test pad and comprises the second test pad; and
performing the second test using the second test pad.

Optionally, the method may further comprise:
after the first test is completed: etching a portion of the first test pad which has been exposed during the first test, so as to form a first void in the first test pad; and filling the first void with a dielectric material; and/or
after the second test is completed: etching a portion of the second test pad which has been exposed during the second test, so as to form a second void in the second test pad; and filling the second void with a dielectric material.

Optionally, after the second test is completed, the method may further comprise: forming a second bond layer at a first end of the second wafer structure, wherein the second bond layer is connected to the second top metal layer located in the second wafer at the first end, wherein the second bond layer is used to: hybrid bond the die stack to the first wafer structure; or hybrid bond adjacent die stack layers.

In another aspect, the present invention provides a semiconductor device comprising:
a first wafer structure comprising at least one first wafer, wherein at least one metal pad is formed on a first side of the first wafer structure; and
at least one die stack layer that comprises at least one die stacks and is stacked on a second side of the first wafer structure, wherein the second side is opposite to the first side, and wherein the die stack is vertically interconnected with the first wafer structure,
wherein each die in the die stack comprises a first test pad for testing and screening of a corresponding die, and wherein a first end of each die stack is provided with a second test pad for testing and screening of a corresponding die stack.

Optionally, a protective layer may be further formed on the first side of the first wafer structure, wherein the metal pad is exposed from an opening in the protective layer.

Optionally, each die in the die stack may comprise a second top metal layer, wherein the first test pad is formed in the second top metal layer of the die.

Optionally, the second test pad may be provided in the second top metal layer of a die that is located at the first end, wherein the second top metal layer is away from other die in the die stack, and wherein the second test pad is connected to the first test pad in the second top metal layer; or wherein the second test pad is provided external to the second top metal layer of the die at the first end, wherein the second top metal layer is located away from other die in the die stack, and wherein the second test pad is connected to the first test pad in the second top metal layer.

Optionally, the semiconductor device may further comprise a top cladding metal layer in each die stack, wherein the top cladding metal layer is disposed external to the second top metal layer of a die located at the first end of the die stack, wherein the cladding metal layer comprises the second test pad and is connected to the second top metal layer by the second test pad and the first test pad.

Optionally, the first test pad may contain a first void filled with a dielectric material, and/or wherein the second test pad contains a second void filled with a dielectric material.

Optionally, the first wafer structure may comprise a logic wafer, and the die stack comprises at least two vertically interconnected memory dies.

In the method for fabricating a semiconductor device according to present application, the metal pads are pre-formed on the first side of the first wafer structure before the die stack is stacked on the second side of the first wafer structure. This avoids forming the metal pad after the die stack is stacked, and hence warpage or other distortion that may otherwise occur to the stacked wafer structure during high-temperature treatment involved in the formation of the metal pad, facilitating stacking of more dies and/or wafers together. Further, during obtaining the die stack that is stacked on the first wafer structure, the second wafer structure is formed by stacking second wafers that have passed the first test and then subjected to the second test to screen for die stack that has passed the second test from the die stacks in second wafer structure. In this way, all the die stacks stacked on the surface of the first wafer structure have passed tests, contributing to increased yield of the semiconductor device being fabricated.

The semiconductor device provided by the present application includes a first wafer structure and at least one die stack layer stacked on a second side of the first wafer structure. Each die in the die stacks has a first test pad for testing and screening of corresponding die, and each die stack is provided at one end thereof with a second test pad for testing and screening of the die stack. Using the first and second test pad to test and screen dies in the die stacks and the die stacks can contribute to increased yield of the semiconductor device. Further, metal pads may be formed on a first side of the first wafer structure before the die stacks are stacked on the first wafer structure, avoiding warpage or other distortion possibly otherwise caused by high-temperature treatment if they are formed after the die stacks are stacked. This facilitates stacking of more dies and/or wafers together.

### BRIEF DESCRIPTION OF THE DRAWINGS

FIG. 1 is a schematic flowchart of a method for fabricating a semiconductor device according to embodiments of the present invention.

FIGS. 2A and 2B show schematic cross-sectional views of a first wafer structure formed in a method for fabricating a semiconductor device according to an embodiment of the present invention.

FIGS. 3A to 3F show schematic cross-sectional views of a second wafer structure formed in a method for fabricating a semiconductor device according to an embodiment of the present invention.

FIGS. 4A to 4E show schematic cross-sectional views of structures resulting from steps in a process to stack at least one die stack layer on a first wafer structure and expose metal pads in a method for fabricating a semiconductor device according to an embodiment of the present invention.

FIGS. 5A to 5D show schematic cross-sectional views of structures resulting from steps in a process to form second test pads in a method for fabricating a semiconductor device according to an alternative embodiment of the present invention.

### DETAILED DESCRIPTION

Semiconductor devices and methods for fabricating the same according to particular embodiments of the present invention will be described in detail below with reference to the accompanying drawings. From the following description, advantages and features of the present invention will be more apparent. Note that the figure is provided in a very simplified form not necessarily drawn to exact scale for the only purpose of helping to explain the disclosed embodiments in a more convenient and clearer way.

In wafer-level stacking technology, as the number of stacked wafers increases, the quantity and volume of metal layers within the stacked structure also grow. Compared to structures with fewer stacked wafers, the wafer stack structure with more layers exhibit more serious warpage at high temperature. Such warpage not only tends to fracture layers or films in the wafer stack structure, but also affects its subsequent processing. Additionally, the yield of the wafer stack structure progressively declines with an increasing number of stacked wafers. In order to meet the requirements in terms of warpage and yield, the wafer stack structure obtained by conventional wafer-level stacking techniques contain a small number of stacked wafers (e.g., five or fewer). Embodiments of the present invention provide a method for fabricating a semiconductor device and a semiconductor device. According to the present invention, a large number of wafers can be stacked together, and the resulting wafer stack structure less suffers from the problems of warpage and yield degradation.

The method is first described below.

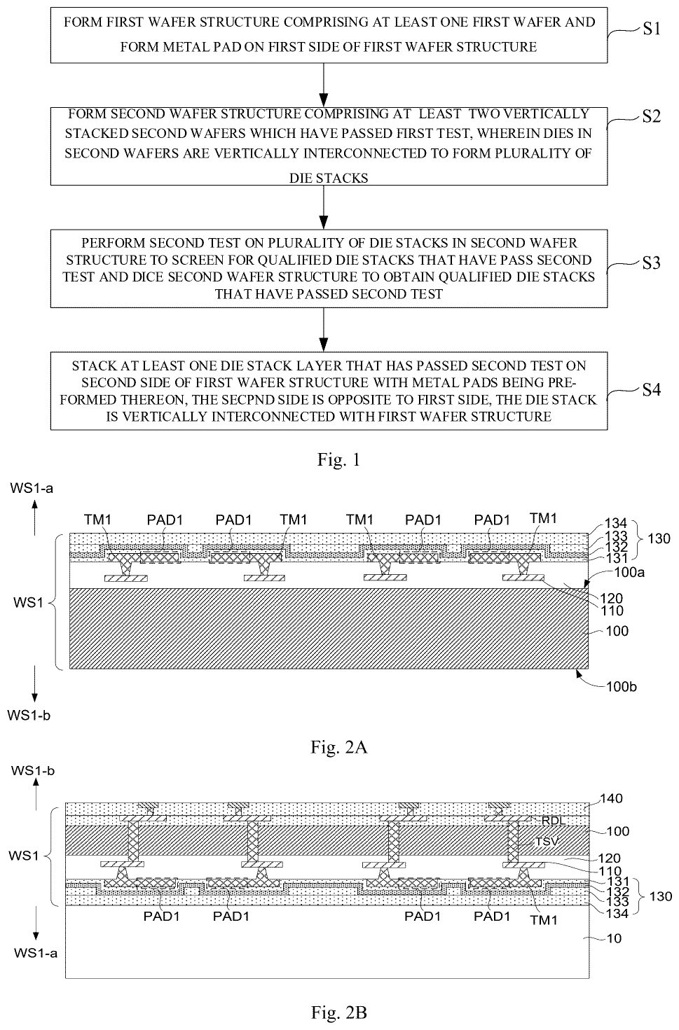

Referring to FIGS. 1 and 2A to 2B, in step S1 of the method for fabricating a semiconductor device according to embodiments of the present invention, a first wafer structure WS1 is formed, the first wafer structure WS1 includes at least one first wafer, and metal pads PAD1 are formed on a first side WS1-a of the first wafer structure WS1.

The at least one first wafer in the first wafer structure WS1 may include electronic components fabricated using semiconductor processes. For example, the at least one first wafer in the first wafer structure may include a logic wafer and/or a memory wafer. The memory wafer may include memory cells, such as non-volatile memory cells or volatile memory cells. Examples of the non-volatile memory cells may include NOR flash memory cells, NAND flash memory cells, ferroelectric memory cells and phase change memory cells. Examples of the volatile memory cells may include DRAM cells and SRAM cells. The logic wafer may include active devices (e.g., MOS transistor) and passive devices.

Referring to FIG. 2A, in some embodiments, the first wafer structure WS1 consists of a single first wafer. For example, the first wafer is a logic wafer. For example, the first wafer includes a first substrate 100 (optionally, silicon, or another suitable material), first interconnect structure 110 formed above a first surface 100a of the first substrate 100 and a dielectric layer 120 surrounding the first interconnect structure 110. In the illustrated embodiment, the first surface 100a is, for example, a surface of the first substrate 100, on which logic devices are formed. The first substrate 100 further has a second surface 100b opposite to the first surface 100a. The first side WS1-a of the first wafer structure WS1 is, for example, provided by the first surface 100a of the first substrate 100.

The metal pads PAD1 are formed on the first side WS1-a of the first wafer structure WS1 before dies are stacked on the first wafer structure WS1. Referring to FIG. 2A, as an example, after the first interconnect structure 110 and the dielectric layer 120 are formed above the first surface 100a of the first substrate 100, a first top metal layer TM1 may be formed above the first interconnect structure 110 and is isolated from the first interconnect structure 110 by the dielectric layer 120 while being connected to the first interconnect structure 110 by a via formed in the dielectric layer 120 (although not shown, a surface of a portion of the first top metal layer TM1 located right above the via may be lower than a surface of a remaining portion of the first top metal layer TM1). The first top metal layer TM1 contains the metal pad PAD1. The first top metal layer TM1 may additionally include other structures necessary for the semiconductor device, such as metal wire connecting the metal pad PAD1.

In order to provide protection to the metal pad PAD1 and facilitate subsequent bonding of the first wafer structure WS1 to die stacks, after the metal pad PAD1 is formed, the first wafer structure WS1 may be processed, as described below.

First of all, a protective layer is formed over the side of the first wafer structure WS1 with the metal pad PAD1 being formed thereon, i.e., the first side WS1-a. In particular, referring to FIG. 2A, as an example, a first oxide layer 131 (e.g., silicon oxide) and a nitride layer 132 (e.g., silicon nitride) may be formed on the first top metal layer TM1 and the dielectric layer 120 surrounding the first top metal layer TM1, and a second oxide layer 133 (e.g., silicon oxide) may be then formed thereon so that its top surface is higher than the nitride layer 132. Subsequently, a planarization process (e.g., chemical mechanical polishing (CMP), with the nitride layer 132 serving as a polish stop layer), may be carried out, and a third oxide layer 134 may be formed thereon. The first oxide layer 131, the nitride layer 132, the second oxide layer 133 and the third oxide layer 133 make up the protective layer 130.

Next, referring to FIG. 2B, the first wafer structure WS1 is bonded at the first side WS1-a to a first carrier substrate 10. Since the protective layer 130 has a planar top surface away from the metal pad PAD1, the bonding to the first carrier substrate 10 can be accomplished easily. Referring to FIG. 2B, after bonded to the first carrier substrate 10, the first substrate 100 may be thinned at the second surface 100b, and on a second side WS1-b of the first wafer structure WS1 (in the illustrated embodiment, the second side WS1-b is provided by the second surface 100b of the first substrate 100), may be successively formed through-silicon via (TSV) connected to the first interconnect structure 110, a rewiring layer RDL and a first bond layer 140 interconnect structure. The first bond layer 140 is used for subsequent hybrid bonding of the first wafer structure WS1 to a die stack.

Here, the term “hybrid bonding” refers to a direct bonding process involving applying a dielectric material (e.g., SiO₂ or SiCN) to surfaces of two semiconductor structures to be bonded to each other and forming metal bond pad and metal bond via in the dielectric material, thereby forming the bond layer. The metal bond pad and metal bond via in the bond layer are connected to circuit within the semiconductor structure. When performing a hybrid bonding, the surfaces of the bonding layer of two semiconductor structures are bonded, so that the dielectric material and the metal bond pad on one semiconductor structure are bonded to the dielectric material and the metal bond pad on the other semiconductor structure, respectively, establishing interconnections between the circuits within the two semiconductor structures.

In the above embodiment, the first wafer structure WS1 includes a single first wafer. The metal pad PAD1 and the protective layer 130 are formed on the first side WS1-a of the first wafer structure WS1, and the second surface 100b of the first substrate 100 provides the second side WS1-b of the first wafer structure WS1. When any process is being performed on the second side WS1-b of the first wafer structure WS1, the first carrier substrate 10 may serve as a support substrate. After all necessary processes on the second side WS1-b are completed, the first carrier substrate 10 may be removed, and the opening may be formed in the protective layer 130, from which the metal pad PAD1 is exposed.

In some embodiments, the first wafer structure WS1 formed in step S1 may consist of at least two stacked first wafers. In these embodiments, for example, adjacent first wafers may be bonded together by hybrid bonding, thereby interconnecting electronic components therein. Alternatively, the at least two first wafers may also be stacked to form the first wafer structure WS1 using any other suitable method known in the art. During stacking of the first wafers, the topmost first wafer and bottommost first wafer each have a side not bonded to any other first wafer. Before or after the at least two first wafers are stacked, the first top metal layer TM1 that contains the metal pad PAD1 may be formed on one side of the bottommost first wafer or topmost first wafer, the first top metal layer TM1 may be connected to metal interconnect structure in a corresponding first wafer. Forming the metal pad PAD1 before the first wafer structure WS1 is bonded to die stack (step S3 of FIG. 1) can avoid forming the metal pad PAD1 after bonding of the first wafer structure WS1 to the die stack, which requires high-temperature treatment, thereby avoiding warpage or other distortion caused by the high-temperature treatment. Moreover, in this way, more dies are allowed to be stacked in the resulting semiconductor device. In one embodiment, before the at least two first wafers are stacked together, the first top metal layer TM1 that contains the metal pad PAD1 is formed on a side of one of the first wafers not to be bonded to any other first wafer. In an alternative embodiment, after the at least two first wafers are stacked and interconnected, the first top metal layer TM1 that contains the metal pad PAD1 is formed on a side of one of the first wafers not bonded to any other first wafer. In order to avoid serious warpage of the resulting wafer stack structure caused by high-temperature treatment involved in the formation of the first top metal layer TM1, the number of first wafers that have been stacked at the beginning of the formation of the first top metal layer TM1 is, for example, fewer than 5.

In those embodiments in which the first wafer structure WS1 consists of at least two first wafers, after the metal pad PAD1 is formed, a protective layer 130 may be formed over, and the wafer structure may be bonded to the first carrier substrate 10 at, the side where the metal pad PAD1 is formed (i.e., the first side WS1-a). Moreover, after the at least two first wafers are stacked, a first bond layer that is connected to the metal interconnect structure within the first wafer structure WS1 may be formed on the side away from the metal pad PAD1 (i.e., the second side WS1-b). The first bond layer is used to hybrid bond the first wafer structure WS1 to a die stack (as described in detail below in connection with step S3). The formation of the protective layer 130 and the first bond layer 140, and the bonding of the first carrier substrate 10 may be accomplished in the same way as described above with reference to FIGS. 2A and 2B.

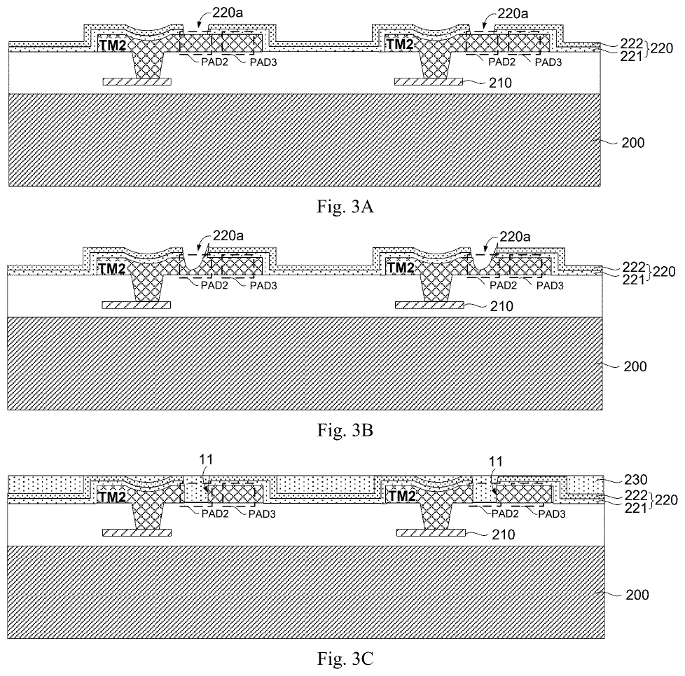

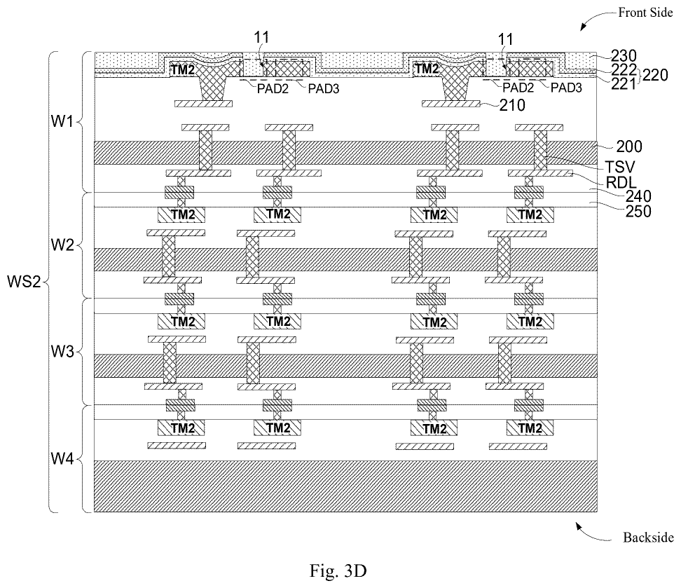

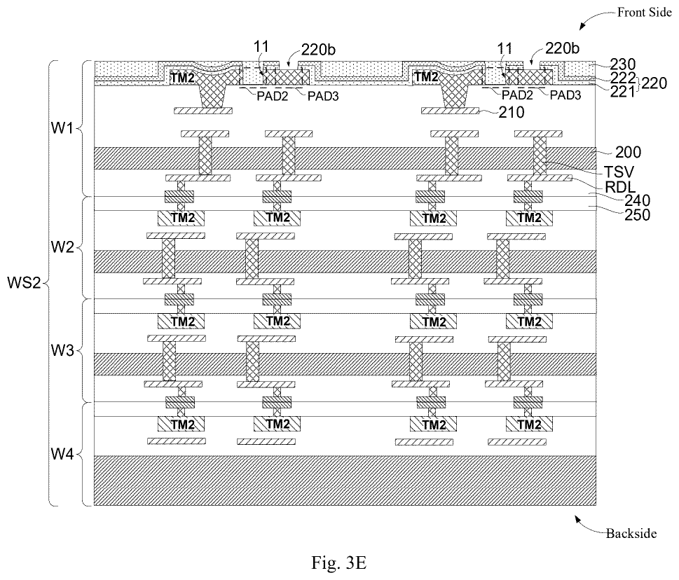

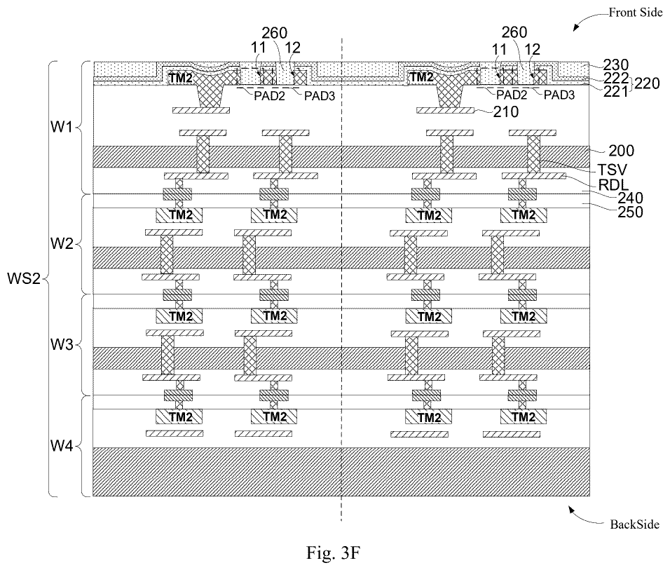

Referring to FIGS. 1 and 3A to 3D, in step S2 of the method for fabricating a semiconductor device according to embodiments of the present invention, a second wafer structure WS2 is formed, the second wafer structure WS2 includes at least two vertically stacked second wafers which have passed a first test. Dies in respective second wafers are vertically interconnected to form a plurality of die stacks.

The second wafer in the second wafer structure WS2 may be selected based on requirements of the semiconductor device. For example, each second wafer may comprise a plurality of die areas and include dies formed in the corresponding die areas. Each die may include electronic components fabricated using semiconductor processes. For example, the second wafer in the second wafer structure WS2 may be memory wafer. In this case, each second wafer may include memory cells, such as DRAM or SRAM, fabricated using semiconductor processes. In the illustrated embodiment, before the second wafer structure WS2 is formed by wafer-to-wafer stacking, a first test is carried out on fed second wafers to select the second wafer satisfying a predefined criterion. For example, the second wafer structure WS2 may be formed, as described below.

At first, referring to FIG. 3A, at least two second wafers are obtained, each including a second top metal layer TM2 containing a first test pad PAD2.

The second wafers are selected from those fed for stacking. Each second wafer has a front side and an opposite backside. For example, electronic components may be formed on the front side.

As shown in FIG. 3A, for example, each second wafer may include a second substrate 200 (optionally, silicon, or another suitable material), a second metal interconnect structure 210 and a second top metal layer TM2 that are formed on the front side of the second substrate 200. For example, the second metal interconnect structure 210 may be connected to electronic components (not shown) formed on the second substrate 200. The second metal interconnect structure 210 may be isolated from the second top metal layer TM2 by a dielectric material while being connected to the second top metal layer TM2 by via formed in the dielectric layer. The second top metal layer TM2 contains first test pad PAD2. The second wafer may additionally include a first passivation layer 220 formed on the second top metal layer TM2, with the first test pad PAD2 of the second top metal layer TM2 being exposed from corresponding first opening 220a in the first passivation layer 220. For example, the first passivation layer 220 may include a stack of an oxide layer 221 and a nitride layer 222. For example, the second metal interconnect structure 210 may include copper. For example, the second top metal layer TM2 may include aluminum. Referring to FIG. 3A, in some embodiments, the second top metal layer TM2 of at least some of the second wafers may further include second test pad PAD3, which is necessary for a second test in step S3, as shown in FIG. 1.

After that, a first test is carried out on the at least two second wafers using the first test pads PAD2, and the second wafer that has passed the test is obtained.

For example, the first test may be a chip probing (CP) test, or a wafer acceptance test (WAT). In the first test, a probe may be used to connect the first test pad PAD2 to a tester to verify performance of the die containing the first test pad PAD2. Based on results of the first test, yield of the second wafer may be calculated, and the second wafer may be then selected based on the yield data. Those second wafers whose yields satisfy a predefined criterion may be considered to pass the first test, and the second stacking structure WS2 is constructed only from second wafers that have passed the first test.

As shown in FIG. 3B, in the first test, damage or even distortion tends to occur to a metal material in exposed regions of the first test pads PAD2, which may affect the performance or subsequent processing of the dies. In order to address this, after the first test, as shown in FIG. 3C, a portion of the first test pad PAD2 exposed during the first test may be etched, for example, using a wet etching process, thereby removing the damage or distortion in the metal material and forming first void 11 (which may extend through the first test pads PAD2, or not) in the first test pad PAD2. After that, a second passivation layer 230 (e.g., silicon oxide) may be formed, which fills the first void and covers an area outside the first void 11. A planarization process may be then carried out so that a top surface of the second passivation layer 230 becomes flush with a top surface of the nitride layer 222.

Afterwards, referring to FIG. 3D, at least two of the second wafers that have passed the first test are selected and stacked to form the second wafer structure WS2, in which adjacent second wafers are hybrid bonded to form a plurality of die stacks.

The at least two second wafers that have passed the first test may be stacked to form the second wafer structure WS2 using any suitable known process. In the second wafer structure WS2, adjacent second wafers are hybrid bonded, thereby interconnecting electronic components formed on the individual second wafer. The number of second wafers in the second wafer structure WS2 may depend on the design of the semiconductor device being fabricated and the capabilities of the processes used. In order to avoid warpage or other issues that may arise from an excessive number of stacked wafers, the number of second wafers in the second wafer structure WS2 may not exceed five, for example.

During the formation of the second wafer structure WS2, if required, the front side of one second wafer may be bonded to the front side of another second wafer. Alternatively or additionally, the front side of one second wafer may be bonded to the backside of another second wafer. As shown in FIG. 3D, for example, the front sides of the second wafers in the second wafer structure WS2 may be oriented in the same direction. For example, the second wafer structure WS2 may include second wafers W1, W2, W3 and W4, which are stacked one on another in a thickness direction thereof. For example, during the formation of the second wafer structure WS2 by stacking the second wafers, the front side of the second wafer W1 may be bonded to a carrier substrate (this may be preceded by forming a dielectric material on the front side of the second wafer W1), and the second substrate 200 in the second wafer W1 may be then thinned from the backside. A TSV may be formed in the second substrate 200 of the second wafer W1 so as to be connected to the second metal interconnect structure 210 in the second wafer W1. Subsequently, a rewiring layer RDL connected to the TSV and a bond layer 240 may be formed. The bond layer 240 may include metal bond pad and metal bond via formed in a dielectric layer, and the metal bond pad and the metal bond via are connected to the rewiring layer RDL and TSV. Further, a bond layer 250 may be formed on the front side of the second wafer W2, which is connected to the second metal interconnect structure 210 in the second wafer W2. The bond layer 250 may include metal bond pad and metal bond via formed in a dielectric layer, and the metal bond pad and metal bond via are connected to the second metal interconnect structure 210 in the second wafer W2. Afterwards, the backside of the second wafer W1 may be bonded to the front side of the second wafer W2 so that the bond layer 240 on the backside of the second wafer W1 is hybrid bonded to the bond layer 250 on the front side of the second wafer W2. This process may be repeated to stack all the other second wafers in the second wafer structure WS2. After all the second wafers are stacked together, the carrier substrate bonded to the front side of the second wafer W1 is removed. The resulting second wafer structure WS2 is shown in FIG. 3D.

In this second wafer structure WS2, the die areas in respective second wafers that are vertically interconnected are vertically aligned, and hence the dies in respective second wafers are vertically aligned, with the electronic components therein being interconnected. Therefore, the second wafer structure WS2 includes a plurality of die stacks consisting of the vertically interconnected dies in the second wafers. In the illustrated embodiment, fabricating the second wafer structure WS2 only from second wafers that have passed the first test contributes to increased yield of the die stack therein.

Referring to FIG. 1, in step S3 of the method for fabricating a semiconductor device according to embodiments of the present invention, a second test is carried out on the die stack in the second wafer structure WS2 to screen for qualified die stack, followed by dicing of the second wafer structure WS2. In this way, die stacks that have passed the second test are obtained.

For example, the second wafer structure WS2 formed in step S2 may comprise a first (or top) end and an opposite second (or bottom) end, the first end and the second end respectively represent two ends of the second wafer structure WS2 along the stacking direction. The first end of the second wafer structure WS2 is provided by one second wafer, and the second end is provided by another second wafer. For example, in the second wafer at the first end (e.g., W1 of FIG. 3D), the second top metal layer TM2 (or first test pad PAD2) is located on the side of the second wafer away from the other second wafer(s) in the second wafer structure WS2. In the second wafer at the second end (e.g., W4 of FIG. 3D), the second top metal layer TM2 (or first test pad PAD2) is located on the side of the second wafer adjacent to the other second wafer(s) in the second wafer structure WS2. In this case, since the second top metal layer TM2 of the second wafer at the first end of the second wafer structure WS2 is more external, the second test may be performed in step S3 on the plurality of die stacks in the second wafer structure WS2 from the first end. However, the present invention is not so limited. In some other embodiments, the second test may also be carried out from the second end.

As shown in FIG. 3D, in some embodiments, the second top metal layer TM2 in at least some of the second wafers in the second wafer structure WS2 may further contain second test pad PAD3, and the second test may be conducted through the second test pad PAD3. When forming the second wafer structure WS2, the second wafer with the second top metal layer TM2 having the second test pad PAD3 may be selected as either the bottom wafer or the top wafer. In this way, the second test pad PAD3 can be more easily exposed subsequently to allow the second test to be carried out. For example, compared to the second wafer W4, the first test pad PAD2 in the second wafer W1 are located on the side away from the other second wafers in the second wafer structure WS2. Therefore, the second test pad PAD3 in the second wafer W1 is also located on the side away from the other second wafers. That is, the second test pad PAD3 is closer to the exterior of the second wafer structure and can be more easily exposed. Accordingly, for example, step S3 may include: forming second opening 220b in the dielectric layer (e.g., the first passivation layer 220) above the second top metal layer TM2, from which the second test pad PAD3 is exposed, for example, by performing photolithography and etching processes, as shown in FIG. 3E; and then performing the second test by connecting the second test pad PAD3 to a tester through a probe. The die stack in the second wafer structure WS2 may be screened based on results of the second test, and qualified die stacks may be then labeled, for example.

In the second test, damage or even distortion tends to occur to a metal material in exposed regions of the second test pad PAD3, which may affect the performance or subsequent processing of the die stack. In order to address this, after the second test, the portion of the second test pad PAD3 exposed during the second test may be etched, for example, using a wet etching process, thereby removing the damage or distortion in the metal material and forming second void 12 (which may extend through the second test pad PAD3, or not) in the second test pad PAD3. After that, a third passivation layer 260 (e.g., silicon oxide) may be formed, which fills the second void 12 and covers the area outside the second void 12. A planarization process may be then carried out so that a top surface of the third passivation layer 260 becomes flush with a top surface of the nitride layer 122, as shown in FIG. 3F.

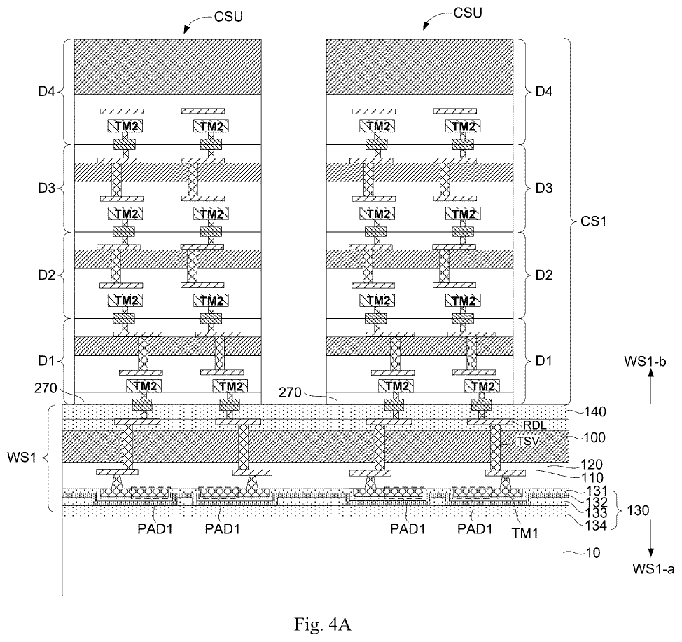

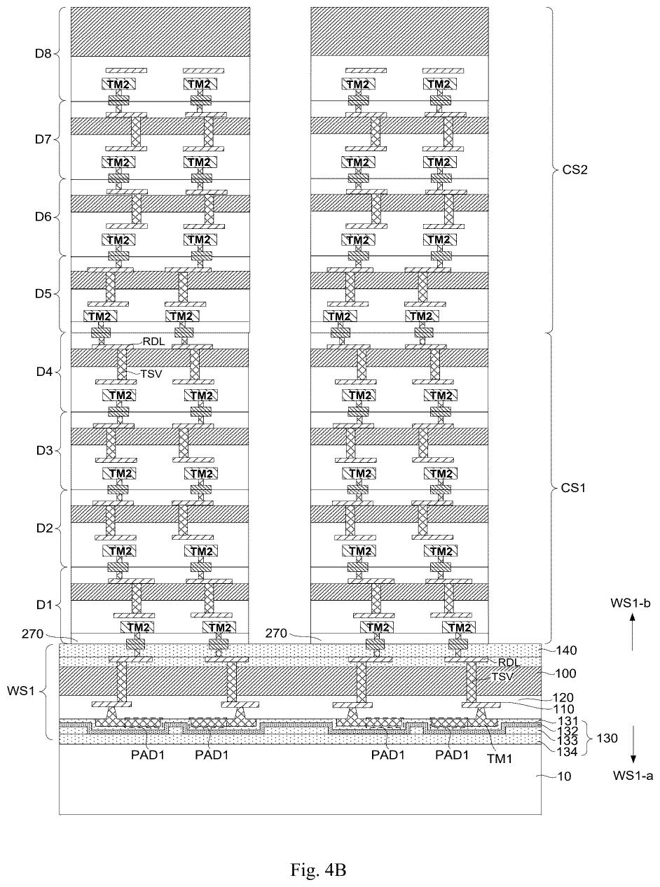

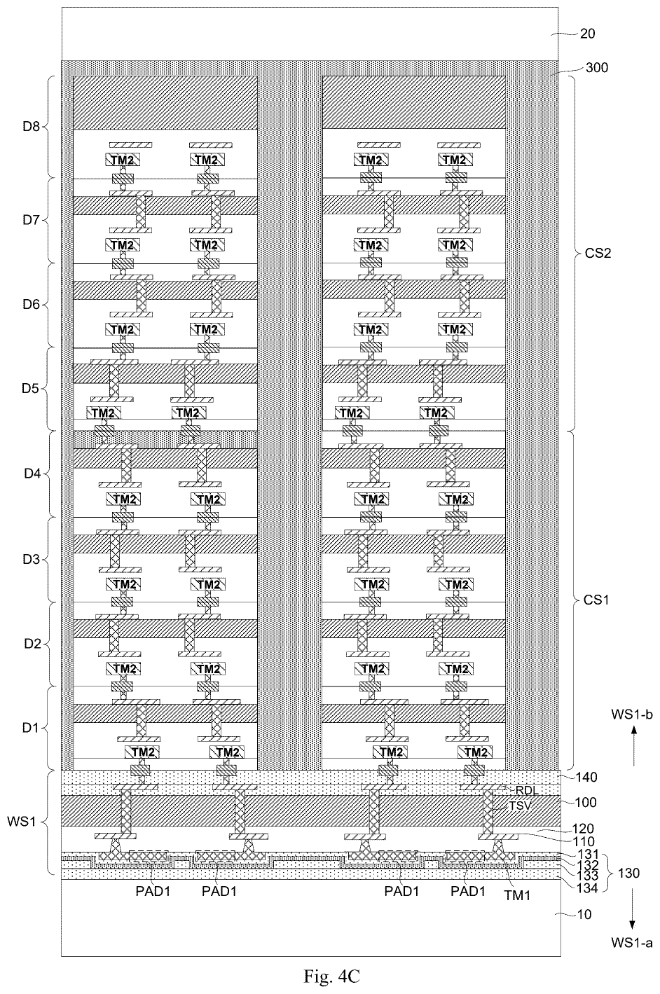

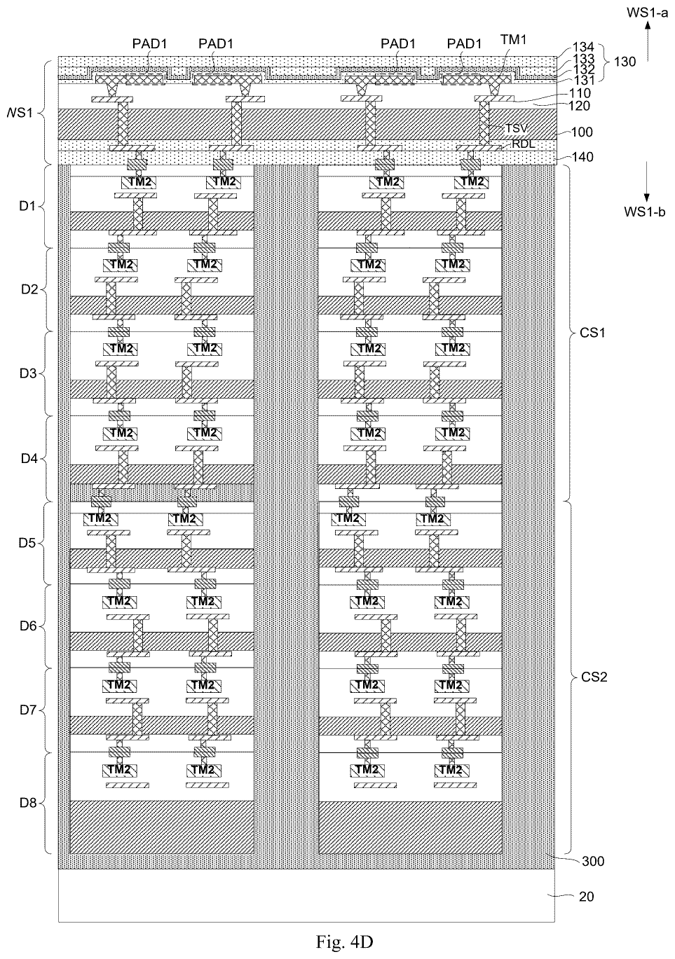

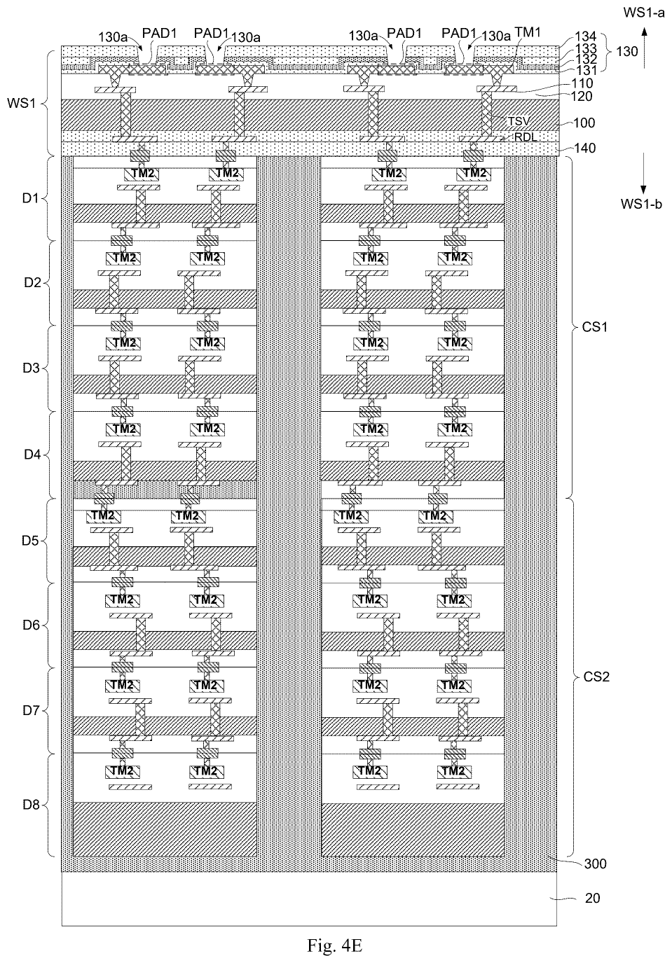

In order to facilitate subsequent bonding of the die stack that has passed the second test to the first wafer structure WS1, or bonding of adjacent die stack layers, after the second wafer structure WS2 is formed, a second bond layer 270 (see FIG. 4A) may be additionally formed on one end thereof. As an example, the second bond layer 270 may include, for example, a dielectric material deposited on the front side of the first wafer W1 and metal bond via and metal bond pad formed in the dielectric material, the second bond layer 270 connects the second top metal layer TM2 in the second wafer W1 through the metal bond pad and metal bond via.

For qualified die stack is identified in the second test, the second wafer structure WS2 may be diced into individual die stacks, for example, along lanes indicated by the dashed line in FIG. 3F. Since the die stack has been verified in the second test, the die stack has passed the second test can be selected after the dicing process. In FIG. 4A, CSU denotes the die stack passing the second test and obtained from the dicing process.

The process to obtain die stack is described above as an illustrative example. It will be understood that the die stack used in subsequent processing may be obtained from either a single second wafer structure WS2, or from different second wafer structures WS2.

Referring to FIG. 1, in step S4 of method for fabricating a semiconductor device according to embodiments of the present invention, at least one die stack layer that has passed the test is stacked on the second side WS1-b of the first wafer structure WS1 that is pre-formed thereon with the metal pad PAD1. The second side WS1-b is opposite to the first side WS1-a, and the die stack is vertically interconnected with the first wafer structure WS1.

For example, the die stack may be bonded to the first wafer structure WS1 of FIG. 2B. In this case, step S4 may include the sub-steps detailed below.

At first, referring to FIG. 4A, one or more of the die stacks that have passed the second test are selected, the second bond layer 270 in the die stack is oriented with the first bond layer 140 in the first wafer structure WS1, followed by hybrid bonding. As a result, a first die stack layer, denoted as CS1, is formed on the second side WS1-b of the first wafer structure WS1. In the first die stack layer CS1, each die stack CSU may include, for example, dies D1-D4 formed from the respective second wafers W1-W4.

Next, referring to FIG. 4B, the die stack CSU is thinned from the side away from the first wafer structure WS1 (e.g., the second substrate on the top of the first die stack layer CS1 is thinned), and TSVs, a rewiring layer RDL and a bond layer are formed therein, which are connected to circuits in the first die stack layer CS1. After that, another one or more of the die stacks CSU that have passed the second test are stacked on the first die stack layer CS1 by hybrid bonding, forming a second die stack layer CS2 located on the first die stack layer CS1, the second die stack layer CS2 is interconnected with the first die stack layer CS1. In the second die stack layer CS2, each die stack may include, for example, dies D5-D8 formed from the respective second wafers W1-W4.

In some embodiments, yet another one or more of the die stacks that have passed the second test may be further stacked on the second die stack layer CS2 to increase the number of dies stacked on the first wafer structure WS1. Through stacking two or more die stack layers on the first wafer structure WS1, the number of die stack layers in the semiconductor device being fabricated can be increased. The number of die stack layers on the first wafer structure WS1 may be determined as needed.

After the at least one die stack layer is stacked on the second side WS1-b of the first wafer structure WS1, the method may further include the steps detailed below.

Referring to FIG. 4C, a molded plastic layer 300 is formed over the second side WS1-b of the first wafer structure WS1, which covers the first wafer structure WS1 and the die stacks and fills gaps between the die stacks. Additionally, a second carrier substrate 20 is bonded to a top surface of the molded plastic layer 300 and the die stacks (e.g., by heat and pressure). In another embodiment, a second carrier substrate 20 may be first bonded above the die stacks, and a molded plastic layer 300 may be then formed in a gap between the first wafer structure WS1 and the second carrier substrate 20.

Referring to FIG. 4D, the first carrier substrate 10 is removed from the first side WS1-a of the first wafer structure WS1, exposing the protective layer 130 that covers the metal pad PAD1.

Referring to FIG. 4E, opening 130a exposing the metal pad PAD1 is formed in the protective layer 130.

Through the metal pad PAD1 exposed on the first side WS1-a of the first wafer structure WS1, the semiconductor device that contains the first wafer structure WS1 and the at least one die stack layer can be connected to an external circuit.

In the embodiments discussed above, the first test pad PAD2 for the first test and the second test pad PAD3 for the second test are formed in the second top metal layer TM2 of the second wafer before the second wafer structure WS2 is formed. The first test pad PAD2 and the second test pad PAD3 may be connected by metal wires in the second top metal layer TM2. Alternatively, they may be formed by different portions of single metal sheet in the second top metal layer TM2 (in this case, they are connected by the other portions of the metal sheet). Thus, the first test pad PAD2 and second test pad PAD3 each occupy dedicated areas within the second top metal layer TM2, and any damage caused to the metal material in the first test pad PAD2 during the first test will not affect the second test pad PAD3, without affecting the second test.

However, the present invention is not so limited. In alternative embodiments, the first test pad PAD2 for the first test may be provided by the second top metal layer TM2, while the second test pad PAD3 for the second test may be formed, after the second wafer structure WS2 is formed by stacking the second wafers, external to the second top metal layer TM2 at one end (e.g., the aforementioned first or second end) of the second wafer structure WS2 (i.e., the side away from the second wafer structure WS2), instead of being provided by the second top metal layer TM2. Additionally, the second test pad PAD3 is connected to the first test pad PAD2 in the corresponding second top metal layer TM2. In these embodiments, since the second test pad PAD3 is provided external to the second top metal layer TM2 (and hence to the first test pad PAD2), no space needs to be reserved for the second test pad PAD3 in the second top metal layer TM2, which helps conserve area in the second top metal layer TM2 and the die stack.

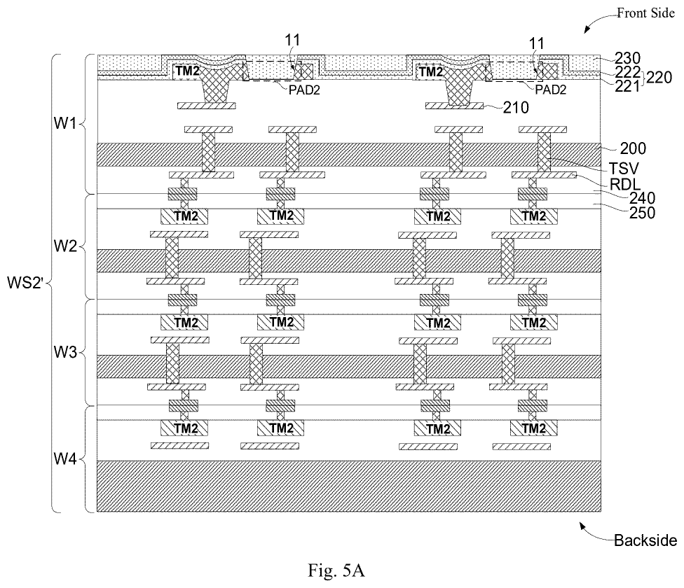

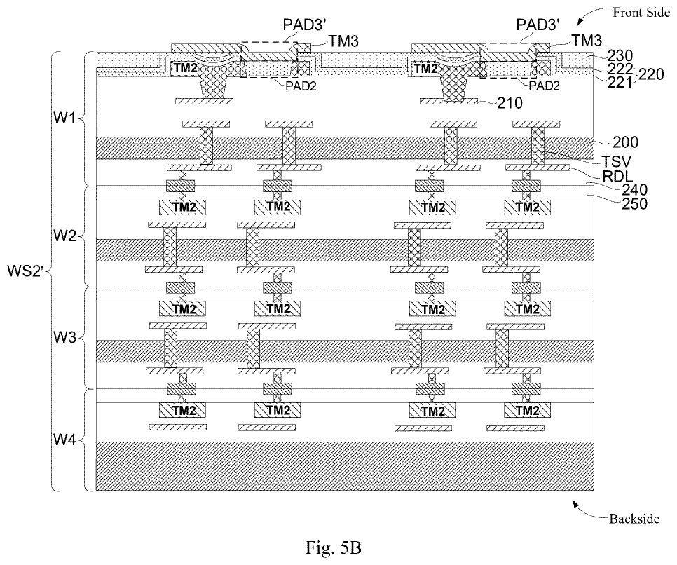

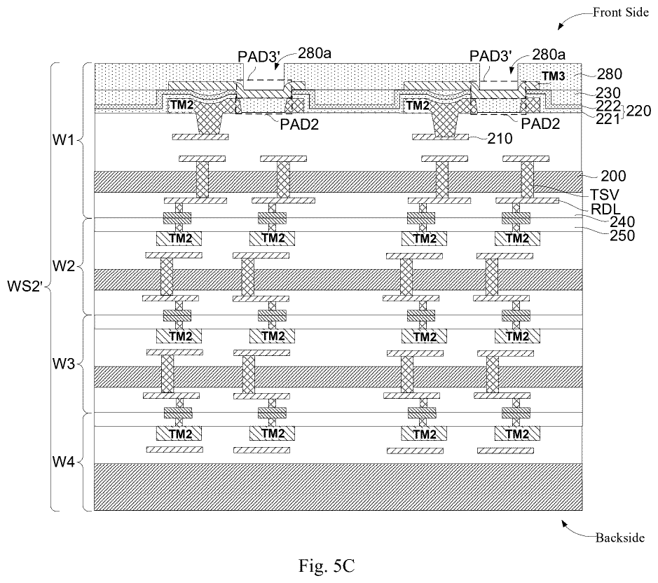

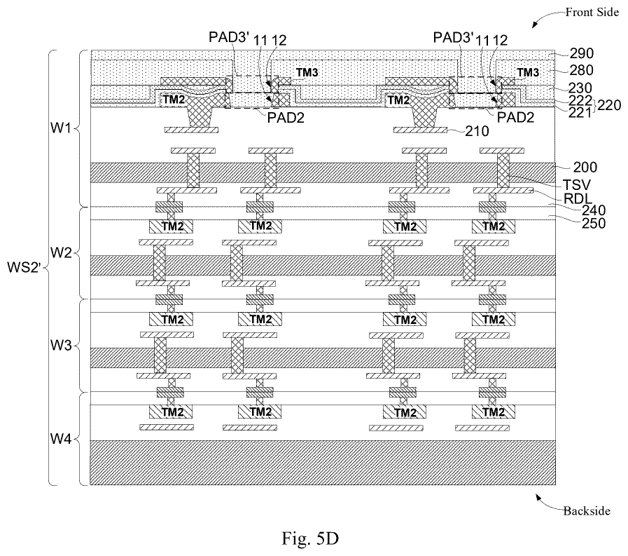

Referring to FIG. 5A, for example, in an alternative embodiment, a second wafer structure WS2′ is formed in step S2 of FIG. 1, which differs from the second wafer structure WS2 formed in step S2 according to the foregoing embodiments in that the second top metal layer TM2 is structured differently. In this alternative embodiment, the second top metal layer TM2 in the second wafer in the second wafer structure WS2′ include the first test pad PAD2 (which may contain the first void 11 that is filled with a dielectric material), but does not include the second test pad PAD3 as described above. In order to allow the second test to be performed on the die stack in the second wafer structure WS2′, according to this alternative embodiment, after the second wafer structure WS2′ is formed (optionally in the same way as described above), the method may further include the steps detailed below.

As shown in FIG. 5B, the first test pads PAD2 is exposed on one side of the second wafer structure WS2′, and a top cladding metal layer TM3 is formed external to the first test pad PAD2 and is connected to the first test pad PAD2. The top cladding metal layer TM3 includes second test pads PAD3′. Since the first test pad PAD2 in the second wafer W1 (i.e., the second wafer in the second wafer structure WS2′ at the first end) is closer to the exterior of the second wafer structure WS2′ than the first test pad PAD2 in the second wafer W4 (i.e., the second wafer in the second wafer structure WS2′ at the second end), the first test pad PAD2 is, for example, exposed from the side of the second wafer W1.

As shown in FIG. 5C, a fourth passivation layer 280 (e.g., silicon oxide) is formed over the top cladding metal layer TM3, and third opening 280a exposing the second test pad PAD3′ is then formed in the fourth passivation layer 280 second test pad.

After the second test pad PAD3′ is exposed in the third opening 280a, step S3 of FIG. 1 may be carried out, in which the second test pad PAD3′ are used to perform the second test on the die stack in the second wafer structure WS2′, and through the second test to select the qualified die stack.

For example, the top cladding metal layer TM3 may have the same pattern as the second top metal layer TM2 prior to the first test (e.g., the top cladding metal layer TM3 is formed by patterning the metal layer using the same photomask employed for forming the second top metal layer TM2). Through patterning the top cladding metal layer TM3 to form the same pattern as the second top metal layer TM2 prior to the first test, a bond layer may be subsequently formed on the top cladding metal layer TM3 and is connected to the top cladding metal layer TM3. Compared to connecting the bond layer to the second top metal layer TM2, this allows metal bond via in the bond layer to have a reduced length, lowering fabrication complexity.

As shown in FIG. 5C, orthographic projection of the second test pads PAD3′ formed in the top cladding metal layer TM3 on a surface of the second top metal layer TM2 may at least partially coincide with the first test pad PAD2 that the second test pad PAD3′ is connected to. However, the present invention is not so limited. Alternatively, the orthographic projection of the second test pad PAD3′ formed in the top cladding metal layer TM3 on the surface of the second top metal layer TM2 may not coincide with the first test pads PAD2 that the second test pad PAD3′ is connected to at all. For example, the second test pad PAD3′ may also be located lateral to the first test pad PAD2 and connected to the second top metal layer TM2 and first test pad PAD2 by the top cladding metal layer TM3.

In the second test, damage or even distortion tends to occur to a metal material in exposed region of the second test pad PAD3′, which may affect the performance or subsequent processing of the die. In order to address this, as shown in FIG. 5D, after the second test, the portion of the second test pad PAD3 exposed during the second test may be etched, for example, using a wet etching process, thereby removing the damage or distortion in the metal material and forming second void 12 (which may extend through the second test pads PAD3′, or not) in the second test pad PAD3′. After that, a fifth passivation layer 290 (e.g., silicon oxide) may be formed, which fills the second void 12 and covers the fourth passivation layer 280. After the second test is completed, a second bond layer may also be formed on the side of the second test pad PAD3′, which can facilitate subsequent bonding and connection of the die stack that has passed the second test to the first wafer structure WS1, or bonding of adjacent die stacks to each other or one another. Reference can be made to the foregoing description for more details of the second bond layer.

After the second wafer structure WS2′ of FIG. 5D is formed, it may be diced into individual die stack, and the die stack that has passed the second test may be obtained. At least one die stack layer that has passed the test are then stacked on the second side WS1-b of the first wafer structure WS1 with the metal pad PAD1 being pre-formed thereon so that the die stack is vertically interconnected with the first wafer structure WS1. After that, as shown in FIGS. 4C to 4E, a molded plastic layer 300 may be additionally formed on the second side WS1-b of the first wafer structure WS1, and a second carrier substrate 20 may be bonded thereto. The first carrier substrate 10 may be then removed, exposing the protective layer 130. Subsequently, opening 130a may be formed in the protective layer 130, in which the metal pad PAD1 is exposed. For details, please refer to the processes performed on the second wafer structure WS2 as discussed above.

Therefore, according to this alternative embodiment, the first and second tests can be carried out using the first test pad PAD2 and the second test pad PAD3′ that is located external (e.g., above), and connected, to the first test pad PAD2, respectively. The second test pad PAD3′ is formed after the second wafer structure WS2′ is formed by stacking the second wafers. In the second test, a probe can be connected to circuits in the second wafer structure WS2′ through the second test pad PAD3′ and the first test pad PAD2. This can ensure reliability of the second test.

In the method for fabricating the semiconductor device according to embodiments as discussed above, the metal pad PAD1 is pre-formed on the first side WS1-a of the first wafer structure WS1 before the die stack is stacked on the second side WS1-b of the first wafer structure WS1. This avoids forming the metal pad PAD1 after the die stacks are stacked, thereby avoiding the high-temperature process for forming metal pad PAD1, which prevents warpage deformation in the stacked wafer structure caused by high-temperature process, facilitating stacking of more dies and/or wafers together. Further, the second wafer structure is formed by stacking second wafers that have passed the first test and then subjected to the second test to screen for qualified die stacks therein. In this way, the die stacks stacked on the surface of the first wafer structure are qualified ones that have passed both tests. This can contribute to increased yield of the semiconductor device.

Embodiments of the present invention also provide a semiconductor device obtainable according to the method for fabricating the semiconductor device according to embodiments as described above.

Referring to FIGS. 2A to 5D, the semiconductor device includes a first wafer structure WS1 and at least one die stack layer (e.g., first die stack CS1 and second die stack CS2 of FIG. 4E). The first wafer structure WS1 includes at least one first wafer, and metal pad PAD1 is formed on a first side WS1-a of the first wafer structure WS1. The at least one die stack layers is stacked on a second side WS1-b of the first wafer structure WS1, which is opposite to the first side WS1-a. The at least one die stack layer is vertically interconnected with the first wafer structure WS1. Each die in the die stack has a first test pad PAD2 for testing and screening for the corresponding die, and each die stack is provided at one end with a second test pad (e.g., second test pad PAD3 of FIG. 3F, or second test pad PAD3′ of FIG. 5D) for testing and screening of the corresponding die stack.

For example, the first wafer structure WS1 may include a logic wafer. For example, each die stack may include at least two vertically interconnected memory dies.

In some embodiments, a protective layer 130 is additionally formed on the first side WS1-a of the first wafer structure WS1, and the metal pad PAD1 is exposed from opening 130a in the protective layer 130.

For example, each die in the die stack may include a second top metal layer TM2, and the first test pad PAD2 of the die may be provided in the second top metal layer TM2.

Referring to FIGS. 3A to 5D, in some embodiments, the second test pad is provided in the second top metal layer TM2 in a die at one end of the die stack, and the second top metal layer TM2 is away from other die(s) in the corresponding die stack. Additionally, the second test pad is connected to the first test pad PAD2 in the corresponding second top metal layer TM2 (e.g., PAD3 of FIGS. 3A to 3F). Alternatively, in some embodiments, the second test pad is provided external to the second top metal layer TM2 in the die located at one end of the die stack, and the second top metal layer TM2 is away from the other die(s) in the corresponding die stack. Moreover, the second test pad is connected to the first test pad PAD2 in the corresponding second top metal layer TM2 (e.g., PAD3′ of FIGS. 5B to 5D).

Referring to FIGS. 5B to 5D, the semiconductor device may include a top cladding metal layer TM3 disposed external to the second top metal layer TM2 in the die at one end of the die stack, wherein the top cladding metal layer TM3 includes a second test pad PAD3′. Additionally, the top cladding metal layer TM3 may be connected to the second top metal layer TM2 by the second test pad PAD3′ and the first test pad PAD2.

Referring to FIGS. 3F and 5D, the first test pad PAD2 may contain a first void filled with a dielectric material. Alternatively or additionally, the second test pad (e.g., the second test pad PAD3 of FIG. 3F, or the second test pad PAD3′ of FIG. 5D) may contain a second void 12 filled with a dielectric material.

In this semiconductor device as described above, the first test pad PAD2 can be used to test and screen the dies in the die stack and the second test pad can be used to test and screen the die stack, thereby contributing to increased yield of the resulting semiconductor device. In addition, the metal pad PAD1 may be formed on the first side WS1-a of the first wafer structure WS1 before the die stack is stacked on the first wafer structure WS1. This avoids forming the metal pad PAD1 after the die stack is stacked, and hence warpage or other distortion that may otherwise occur during high-temperature treatment involved in the formation of the metal pad PAD1. Thus, more dies and/or wafers are allowed to be stacked together.

It is noted that the embodiments disclosed herein are described in a progressive manner, with the description of each embodiment focusing on its differences from others. Cross-reference can be made between the embodiments for their common or similar features.

While the invention has been described above with reference to several preferred embodiments, it is not intended to be limited to these embodiments in any way. In light of the teachings hereinabove, any person of skill in the art may make various possible variations and changes to the disclosed embodiments without departing from the scope of the invention. Accordingly, any and all such simple variations, equivalent alternatives and modifications made to the foregoing embodiments without departing from the scope of the invention are intended to fall within the scope thereof.

What is claimed is:

1. A method for fabricating a semiconductor device, comprising:
forming a first wafer structure comprising at least one first wafer, and forming at least one metal pad on a first side of the first wafer structure;
forming a second wafer structure comprising at least two vertically stacked second wafers that have passed a first test, wherein dies in respective second wafers are vertically interconnected to form a plurality of die stacks;
performing a second test on the plurality of die stacks in the second wafer structure to screen for the die stacks that pass the second test, and dicing the second wafer structure to obtain the die stacks that have passed the second test; and
stacking at least one die stack layer that has passed the second test on a second side of the first wafer structure, wherein the second side is opposite to the first side, and wherein the die stack is vertically interconnected with the first wafer structure.

2. The method of claim 1, wherein the first wafer structure consists of a single first wafer, wherein the first wafer comprises a first substrate, and at least one first interconnect structure and a first top metal layer that are formed on a first surface of the first substrate, wherein the first top metal layer comprises the metal pad.

3. The method of claim 2, further comprising, after the metal pad is formed:
forming a protective layer that covers a side of the first wafer where the metal pad is formed, and bonding a first carrier substrate to the protective layer; and
thinning the first substrate at a second surface that is opposite to the first surface, and forming at least one through-silicon via (TSV), a rewiring layer and a first bond layer that are connected to the first interconnect structure, wherein the first bond layer is used to hybrid bond the die stack to the first wafer structure.

4. The method of claim 3, further comprising, after the at least one die stack layer is stacked on the second side of the first wafer structure:
forming a molded plastic layer over the second side, wherein the molded plastic layer covers the first wafer structure, the die stacks, and fills each gap between the die stacks;
removing the first carrier substrate to expose the protective layer; and
forming at least one opening that exposes the metal pad in the protective layer.

5. The method of claim 1, wherein the first wafer structure is formed by stacking at least two first wafers, wherein before or after the stacking is completed, a first top metal layer containing the metal pad is formed on a first side of one of the first wafers at which other first wafer is not stacked.

6. The method of claim 5, further comprising:
after the metal pad is formed, forming a protective layer that covers the first side of the first wafer where the metal pad is formed, and bonding a first carrier substrate to the protective layer; and
after stacking the at least two first wafers, forming a first bond layer at an end of a resulting stack that is away from the metal pad, wherein the first bond layer is used to hybrid bond the die stack to the first wafer structure.

7. The method of claim 1, wherein forming the second wafer structure comprises:
obtaining at least two second wafers each comprising a second top metal layer, wherein the second top metal layer comprises at least one first test pad;
performing the first test on the at least two first wafers using the first test pad, so as to screen for the second wafer that passes the first test; and
forming the second wafer structure by selecting at least two second wafers that have passed the first test, wherein in the second wafer structure, adjacent second wafers are hybrid bonded to form the plurality of die stacks.

8. The method of claim 7, wherein the second wafer structure comprises a first end, wherein the first test pad located in the second wafer at the first end is located away from the other second wafer(s) in the second wafer structure, and wherein the second test is performed on the die stack from the first end.

9. The method of claim 8, wherein the second top metal layer in the second wafer at the first end further comprises at least one second test pad that is connected to the first test pad, wherein performing the second test on the die stack in the second wafer structure comprises: exposing the second test pad located at the first end; and performing the second test using the second test pad.

10. The method of claim 8, wherein performing the second test on the die stack in the second wafer structure comprises:
exposing the first test pad located at the first end;
forming a top cladding metal layer that is located external to the first test pad, wherein the top cladding metal layer is connected to the first test pad and comprises the second test pad; and
performing the second test using the second test pad.

11. The method of claim 9, further comprising:
after the first test is completed: etching a portion of the first test pad which has been exposed during the first test, so as to form a first void in the first test pad; and filling the first void with a dielectric material; and/or
after the second test is completed: etching a portion of the second test pad which has been exposed during the second test, so as to form a second void in the second test pad;
and filling the second void with a dielectric material.

12. The method of claim 7, further comprising, after the second test is completed:
forming a second bond layer at a first end of the second wafer structure, wherein the second bond layer is connected to the second top metal layer located in the second wafer at the first end, wherein the second bond layer is used to: hybrid bond the die stack to the first wafer structure; or hybrid bond adjacent die stack layers.

13. A semiconductor device, comprising:
a first wafer structure comprising at least one first wafer, wherein at least one metal pad is formed on a first side of the first wafer structure; and
at least one die stack layer that comprises at least one die stack and is stacked on a second side of the first wafer structure, wherein the second side is opposite to the first side, and wherein the die stack is vertically interconnected with the first wafer structure,
wherein each die in the die stack comprises a first test pad for testing and screening of a corresponding die, and wherein a first end of each die stack is provided with a second test pad for testing and screening of a corresponding die stack.

14. The semiconductor device of claim 13, wherein a protective layer is further formed on the first side of the first wafer structure, and wherein the metal pad is exposed from an opening in the protective layer.

15. The semiconductor device of claim 13, wherein each die in the die stack comprises a second top metal layer, wherein the first test pad is formed in the second top metal layer of the die.

16. The semiconductor device of claim 15, wherein the second test pad is provided in the second top metal layer of a die that is located at the first end, wherein the second top metal layer is away from other die in the die stack, and wherein the second test pad is connected to the first test pad in the second top metal layer; or wherein the second test pad is provided external to the second top metal layer of the die at the first end, wherein the second top metal layer is located away from other die in the die stack, and wherein the second test pad is connected to the first test pad in the second top metal layer.

17. The semiconductor device of claim 15, further comprising a top cladding metal layer in each die stack, wherein the top cladding metal layer is disposed external to the second top metal layer of a die located at the first end of the die stack, wherein the cladding metal layer comprises the second test pad and is connected to the second top metal layer by the second test pad and the first test pad.

18. The semiconductor device of claim 16, wherein the first test pad contains a first void filled with a dielectric material, and/or wherein the second test pad contains a second void filled with a dielectric material.

19. The semiconductor device of claim 13, wherein the first wafer structure comprises a logic wafer, and the die stack comprises at least two vertically interconnected memory dies.
